(19) United States
(12) Patent Application Publication
(10) Pub. No.: US 2016/0086943 A1
(43) Pub. Date: Mar. 24, 2016

(54) SEMICONDUCTOR DEVICE AND METHOD FOR MANUFACTURING SEMICONDUCTOR DEVICE

(71) Applicants: Sun Young LEE, Yongin-si (KR); Jae Young Park, Yongin-si (KR); Han Ki Lee, Hwaseong-si (KR); Bon Young Koo, Suwon-si (KR); Hong Bum Park, Seoul (KR); Young Su Chung, Suwon-si (KR); Jae Jong Han, Seoul (KR)

(72) Inventors: Sun Young LEE, Yongin-si (KR); Jae Young Park, Yongin-si (KR); Han Ki Lee, Hwaseong-si (KR); Bon Young Koo, Suwon-si (KR); Hong Bum Park, Seoul (KR); Young Su Chung, Suwon-si (KR); Jae Jong Han, Seoul (KR)

(21) Appl. No.: 14/857,135

(22) Filed: Sep. 17, 2015

(30) Foreign Application Priority Data
Sep. 18, 2014 (KR) 10-2014-0124472

(51) Int. Cl. H01L 27/088; H01L 29/423; H01L 29/06

(52) U.S. Cl. CPC H01L 27/0886; H01L 29/0649; H01L 29/0684; H01L 29/42368

(57) ABSTRACT

A semiconductor device includes a substrate, an isolation layer on the substrate, and at least one active fin on the substrate. The isolation layer includes a first surface opposite a second surface. The first surface is contiguous with the substrate. The at least one active fin protrudes from the substrate and includes a first region having a side wall above the second surface of the isolation layer and a second region on the first region. The second region has an upper surface. The first region has a first width contiguous with the second surface of the isolation layer and a second width contiguous with the second region. The second width is 60% or greater than the first width (e.g., 60% to 100%).

### CROSS-REFERENCE TO RELATED APPLICATION

This application claims priority under 35 U.S.C. §119 to Korean Patent Application No. 10-2014-0124472 filed on Sep. 18, 2014, with the Korean Intellectual Property Office, the entire disclosure of which is incorporated herein by reference.

### BACKGROUND

The present disclosure relates to a semiconductor device and a method for manufacturing a semiconductor device.

Complementary metal oxide silicon (CMOS) field effect transistors (FETs) have been continuously reduced in size due to demand for high degrees of integration thereof. However, as the channel length is reduced, degradations in functionality due to a short channel effect may be problematic. Thus, a fin-shaped field effect transistor (Fin-FET) has been proposed to realize a transistor capable of reducing the short-channel effect.

### SUMMARY

Example embodiments of inventive concepts may provide a highly integrated and highly efficient semiconductor device.

Example embodiments of inventive concepts may also provide a method for effectively manufacturing a semiconductor device.

According to example embodiments of inventive concepts, a semiconductor device may include: a substrate; an isolation layer on the substrate, the isolation layer having a first surface opposite a second surface, the first surface being contiguous with the substrate; and at least one active fin protruding from the substrate and including a first region having a side wall above the second surface of the isolation layer and a second region on the first region, the second region having an upper surface, the first region having a first width contiguous with the second surface of the isolation layer and a second width contiguous with the second region, and the second width being in a range of 60% to 100% of the first width.

In example embodiments, the at least one active fin may include a corresponding active fin protruding above the isolation layer. The first and second widths may be widths of the corresponding active fin at first and second heights with respect to the second surface of the isolation layer, and the first height may be greater than 0% and less than or equal to 6% of a height of the corresponding active fin protruding above the isolation layer, and the second height may be greater than or equal to 85% of the height of the corresponding active fin protruding above the isolation layer and less than the height of the corresponding active fin protruding above the isolation layer.

In example embodiments, the at least one active fin may include a corresponding active fin protruding above the isolation layer. The first width may be a width of the corresponding active fin at a level 2 nm higher than the second surface of the isolation layer, and the second width may be a width of the corresponding active fin at a level 5 nm lower than a height of the corresponding active fin protruding above the isolation layer.

In example embodiments, the second width may have a size ranging from 60% to 75% of the first width.

In example embodiments, the upper surface may be a curved surface, and a radius of curvature of the upper surface may range from 3.5 nm to 5 nm.

In example embodiments, the at least one active fin may include a corresponding active fin. A side wall of the corresponding active fin may have an angle ranging from 85° to 90° with respect to the second surface of the isolation layer.

In example embodiments, a side wall of the at least one active fin may have a crystal structure in which a crystal plane is a (110) plane.

In example embodiments, the semiconductor device may further include a gate insulating layer including a first insulating layer and a second insulating layer on the first insulating layer. The at least one active fin may include a corresponding active fin. The gate insulating layer may be on the corresponding active fin. The gate insulating layer may cover a side wall and the upper surface of the corresponding active fin.

In example embodiments, a thickness of the second insulating layer may be greater than a thickness of the first insulating layer.

In example embodiments, the thickness of the first insulating layer may range from 20 Å to 35 Å, and the thickness of the second insulating layer may range from 35 Å to 45 Å.

In example embodiments, the first and second insulating layer may be formed of a same material.

In example embodiments, a thickness of a region of the gate insulating layer on the upper surface of the corresponding active fin may be 96% to 106% of a thickness of a region of the gate insulating layer on the side wall of the corresponding active fin.

In example embodiments, the semiconductor device may further include a gate electrode on the gate insulating layer.

According to example embodiments of inventive concepts, a semiconductor device may include: a substrate; an isolation layer on the substrate, the isolation layer having a first surface opposite a second surface, the first surface being contiguous with the substrate; and at least one active fin on the substrate. The at least one active fin includes a corresponding active fin. The corresponding active fin has a side wall and an upper surface protruding from the second surface of the isolation layer. The corresponding active fin includes a region in which a width thereof increases in a direction toward the substrate from the upper surface, and a height at which a width of the corresponding active fin is 4 nm is a height equal to 97% or greater of the height of the corresponding active fin and less than height of the corresponding active fin.

In example embodiments, the height at which the width of the corresponding active fin is 4 nm may be at a level 0.9 nm or lower than the height of the corresponding active fin.

According to example embodiments of inventive concepts, a semiconductor device may include a substrate including a trench that defines an active fin and an isolation layer in the trench. The active fin may include a protruding region that extends upward from a buried region. The protruding region and the buried region each respectively may include a central axis that extends in a height direction thereof. A difference in angle between the central axis of the buried region and the central axis of the protruding region may be less than or equal to 3°. The protruding region may include a first region and a second region that is above the first region. The second region may include a curved upper surface. The isolation layer may surround the buried region of the active fin such that the protruding region of the active fin protrudes above the isolation layer.

In example embodiments, the semiconductor device may further include a gate insulating layer covering the protruding region and a gate electrode on the gate insulating layer. The gate insulating layer may cover the curved upper surface of the second region of the protruding region. The gate insulating may extend from the curved upper surface to cover a sidewall of the protruding region along the first and second region. A thickness of the gate insulating layer on the curved upper surface of the second region may be 96% to 106% of a thickness of the gate insulating layer along the sidewall of the protruding region at the first region of the protruding region.

In example embodiments, the gate insulating layer may include a first insulating layer and a second insulating layer. The thickness of the first insulating layer may range from 20 Å to 35 Å, and the thickness of the second insulating layer may range from 35 Å to 45 Å.

In example embodiments, the curved upper surface of the second region may have a radius of curvature that ranges from 3.5 nm to 5 nm.

In example embodiments, the protruding region may have a first width at a first height and a second width at a second height. The first height may be greater than 0% of a height of the protruding region and less than or equal to 6% of the height of the protruding region. The second height may be less than the height of the protruding region and greater than 85% of the height of the protruding region. The second width may have a size ranging from 60% to 75% of the first width.

According to example embodiments of inventive concepts, a method for manufacturing a semiconductor device may include: forming a trench in a substrate, the trench defining at least one active fin, the at least one active fin including a corresponding active fin; forming an isolation layer filling a portion of the trench such that the corresponding active fin protrudes above the isolation layer; forming a first insulating layer on the protruded region of the corresponding active fin using a first oxidation process with a first temperature range; and forming a second insulating layer on the first insulating layer using a second oxidation process, the second oxidation process being different from the first oxidation process, the second oxidation process including a second temperature range that is higher than the first temperature range.

In example embodiments, the first temperature range may be 400° C. to 600° C.

In example embodiments, the second temperature range may be 800° C. to 1050° C.

In example embodiments, the first oxidation process may include a plasma radical oxidation process. The second oxidation process may include a thermal radical oxidation process.

In example embodiments, the second insulating layer may be formed to have a thickness greater than a thickness of the first insulating layer.

In example embodiments, the thickness of the first insulating layer may range from 20 Å to 35 Å. The thickness of the second insulating layer may range from 35 Å to 45 Å.

In example embodiments, the method may further include surface-treating the protruded region of the corresponding active fin before the forming the first insulating layer. The surface-treating may include performing a plasma process using at least one of hydrogen and an inert gas at a temperature ranging from 300° C. to 700° C.

In example embodiments, the method may further include forming a gate electrode on the second insulating layer after the forming of the second insulating layer.

In example embodiments, after the forming the second insulating layer, the corresponding active fin may have a first width at a first height at a level 2 nm higher than an upper surface of the isolation layer and a second width at a second height at a level 5 nm lower than the upper surface of the corresponding active fin, and the second width may range from 60% to 100% of the first width.

In example embodiments, after the forming the second insulating layer, the corresponding active fin may include a region in which a width thereof increases in a direction toward the substrate, and a height at which the width of the corresponding active fin is 4 nm may be at a level of 0.3 nm to 0.9 nm lower than the height of the upper surface of the corresponding active fin.

In example embodiments, after the forming the second insulating layer, an upper surface of the corresponding active fin may have a radius of curvature ranges from 3.5 nm to 5 nm.

According to example embodiments of inventive concepts, a method for manufacturing a semiconductor device may include: forming at least one active fin on a substrate, the at least one active fin including a corresponding active fin; forming a first insulating layer on the corresponding active fin by using at least one of a nitriding process and a deposition process within a first temperature range; and forming a second insulating layer on the first insulating layer by using an oxidation process within a second temperature range higher than the first temperature range.

In example embodiments, the forming the first insulating layer may include the nitriding process. The nitriding process may include a plasma radical nitriding process.

In example embodiments, the forming the first insulating layer may include depositing at least one of a silicon oxide, a silicon nitride, and a silicon oxynitride on the corresponding active fin.

In example embodiments, the forming the first insulating layer may include the deposition process. The deposition process may include at least one of a chemical vapor deposition (CVD) process and an atomic layer deposition (ALD) process.

In example embodiments, the first temperature range may be 400° C. to 600° C. and the second temperature range may be 800° C. to 1050° C.

According to example embodiments of inventive concepts, a method for manufacturing a semiconductor device includes: forming a trench in a substrate, the trench defining an active fin; forming an isolation layer filling a portion of the trench such that the active fin includes a buried region being covered by the isolation layer and a protruding region protruding above the isolation layer; and forming a gate insulating layer on the protruding region by a first oxidation process at a the first temperature and a second oxidation process at a second temperature higher than the first temperature such that the protruding region includes a curved upper surface. The protruding region covered by the gate insulating layer and the buried region each respectively include a central axis that extends in a height direction thereof. A difference in angle between the central axis of the buried region and the central axis of the protruding region ranges from 0° to 3°.

In example embodiments, the first temperature range may be 400° C. to 600° C. and the second temperature range may be 800° C. to 1050° C.

In example embodiments, the first oxidation process may include a plasma radical oxidation process. The second oxidation process may include a thermal radical oxidation process.

In example embodiments, a thickness of the gate insulating layer on the curved upper surface of the protruding region may be 96% to 106% of a thickness of the gate insulating layer along on a sidewall of the protruding region.

### BRIEF DESCRIPTION OF DRAWINGS

The foregoing and other features of inventive concepts will be apparent from the more particular description of non-limiting embodiments of inventive concepts, as illustrated in the accompanying drawings in which like reference characters refer to like parts throughout the different views. The drawings are not necessarily to scale, emphasis instead being placed upon illustrating principles of inventive concepts. In the drawings:

FIG. 1 is a perspective view schematically illustrating a semiconductor device according to example embodiments of inventive concepts;

FIG. 2 is an enlarged view of a region “R” of FIG. 1;

FIG. 3 is a graph illustrating variations in driving currents according to widths of active fins of a fin-shaped field effect transistor (FinFET).

FIGS. 4 and 5 are flow charts illustrating a method for manufacturing a semiconductor device according to example embodiments of inventive concepts;

FIGS. 6A through 6H are cross-sectional views sequentially illustrating processes of a method for manufacturing a semiconductor device according to example embodiments of inventive concepts;

FIGS. 7A and 7B are cross-sectional views sequentially illustrating processes of a method for manufacturing a semiconductor device according to example embodiments of inventive concepts;

FIG. 8 is a perspective view schematically illustrating a semiconductor device according to example embodiments of inventive concepts;

FIGS. 9A and 9B are a perspective view and a cross-sectional view illustrating a semiconductor device according to example embodiments of inventive concepts;

FIGS. 10A and 10B are comparative photographs illustrating shapes of active fins of a semiconductor device according to example embodiments of inventive concepts;

FIG. 11 is a circuit diagram of a CMOS inverter including a semiconductor device according to example embodiments of inventive concepts;

FIG. 12 is a circuit diagram of an SRAM cell including a semiconductor device according to example embodiments of inventive concepts; and

FIGS. 13 and 14 are block diagrams illustrating an electronic device and a storage device including a semiconductor device according to example embodiments of inventive concepts.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference characters and/or numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items.

It will be understood that, although the terms “first”, “second”, etc. may be used herein to describe various elements, components, regions, layers and/or sections. These elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

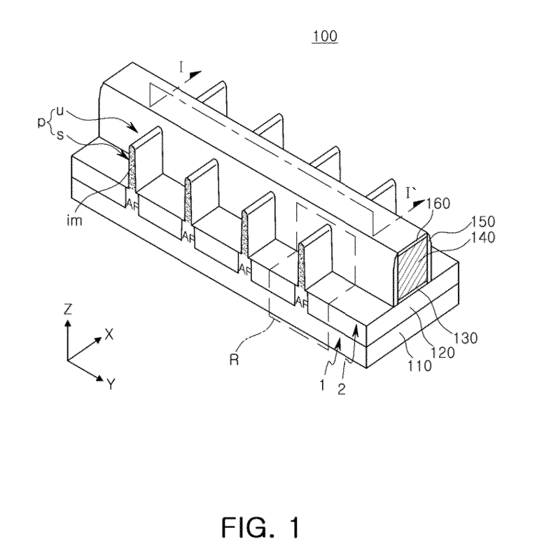

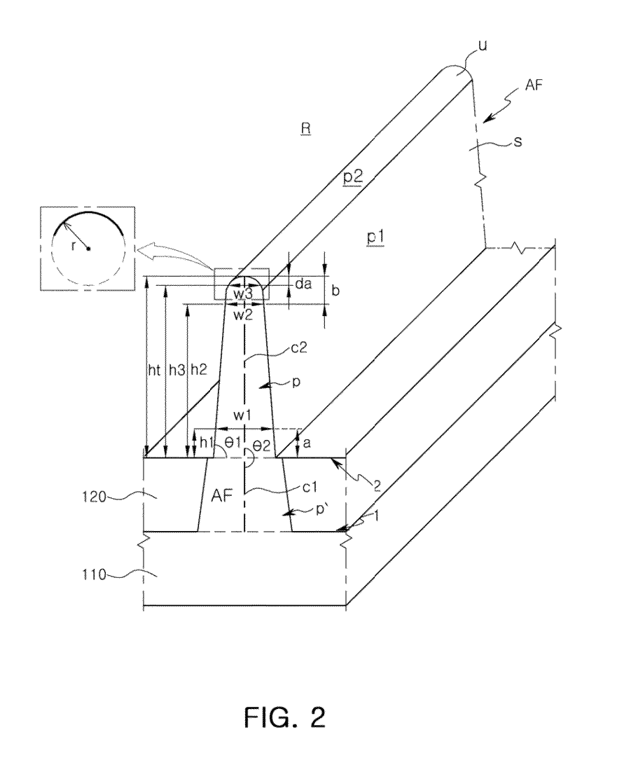

FIG. 1 is a perspective view schematically illustrating a semiconductor device 100 according to example embodiments of inventive concepts, and FIG. 2 is an enlarged view of a region “R” of FIG. 1. The region “R” of FIG. 1 may be referred to as a corresponding active fin because one active fin is illustrated in FIG. 2.

Referring to FIG. 1, in example embodiments, a semiconductor device 100 includes a substrate 110, and an isolation layer 120 and at least one active fin AF disposed on the substrate 110. A gate insulating layer 130 and a gate electrode 140 may be disposed on the at least one active fin (AF).

The substrate 110 may be bulk silicon or a semiconductor-on-insulator substrate, such as a silicon-on-insulator (SOI) substrate. However, without being limited thereto, the substrate 110 may be formed of a semiconductor material selected from the group consisting of Si, Ge, SiGe, GaP, GaAs, SiC, SiGeC, InAs, and InP. Also, the substrate 110 may include a base substrate and an epitaxial layer formed on the base substrate.

The isolation layer 120 may be disposed on the substrate 110. The isolation layer 120 may have a first surface 1 contiguous with the substrate 110 and a second surface 2 opposing the first surface 1.

According to example embodiments, in a case where the at least one active fin AF is provided as a plurality of active fins (AF), the plurality of active fins AF may be defined by the isolation layer 120.

The isolation layer 120 may include an insulating material, for example, an oxide, a nitride, and/or an oxynitride. For example, the isolation layer 120 may be formed of at least one of a boron-phosphor silicate glass (BPSG), a high density plasma (HDP) oxide, a flowable oxide (FOX), a tonen silazene (TOSZ), a spin on glass (SOG), an undoped silica glass (USG), a tetraethyl ortho silicate (TEOS), and a low temperature oxide (LTO), but is not limited thereto.

The active fins AF may upwardly protrude from the substrate 110 in a first direction (a Z direction) and extend in a second direction (an X direction). In this case, the active fins AF may have a width according to a third direction (a Y direction) transverse to the second direction (the X direction). In detail, the active fins AF protrude from the substrate 110 in the first direction (the Z direction) to have a region p protruding above the second surface 2 of the isolation layer 120. The protruded region P may include a side wall s and an upper surface u.

The active fins AF may include silicon germanium, or silicon-germanium. Also, the active fins AF may include a compound semiconductor, for example, a Group IV-IV compound semiconductor or a Group III-V compound semiconductor.

The active fin AF may be formed by etching portions of the substrate 110, but the method of forming the active fins AF is not limited thereto. For example, the active fins AF may also be formed by performing a selective epitaxial growth (SEG) on the substrate 110.

Impurity regions im corresponding to source and drain regions may be formed in partial regions of the active fins AF. The impurity regions im may be formed by implanting impurities into regions of the active fins AF not overlapping with the gate electrode 140. However, the present inventive concept is not limited thereto and, a process of growing the impurity regions im and implanting impurities thereinto may also be used.

The impurity regions im may include a p-type impurity when the semiconductor device 100 is a PMOS transistor. Alternatively, the impurity regions im may include n-type impurity when the semiconductor device 100 is an NMOS transistor.

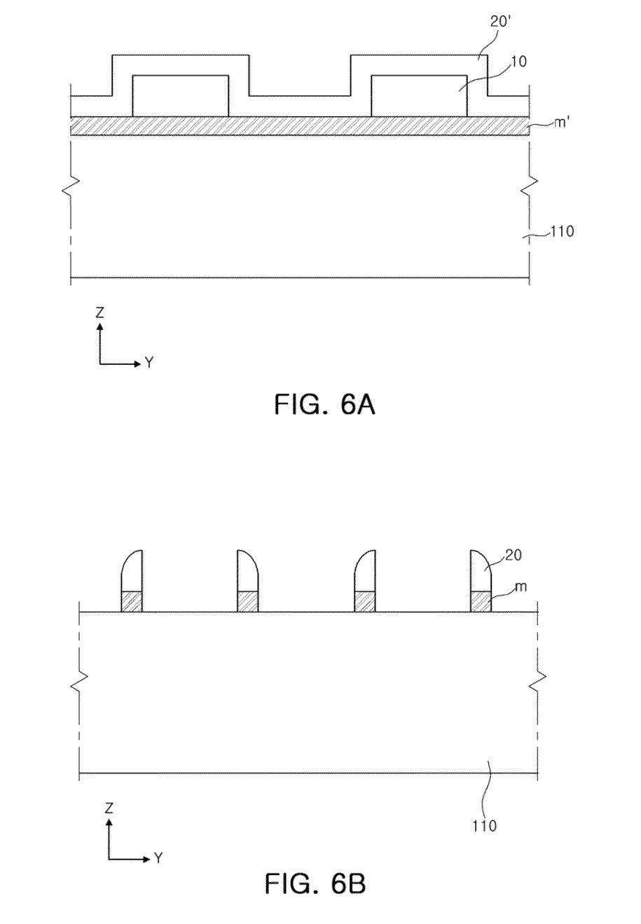

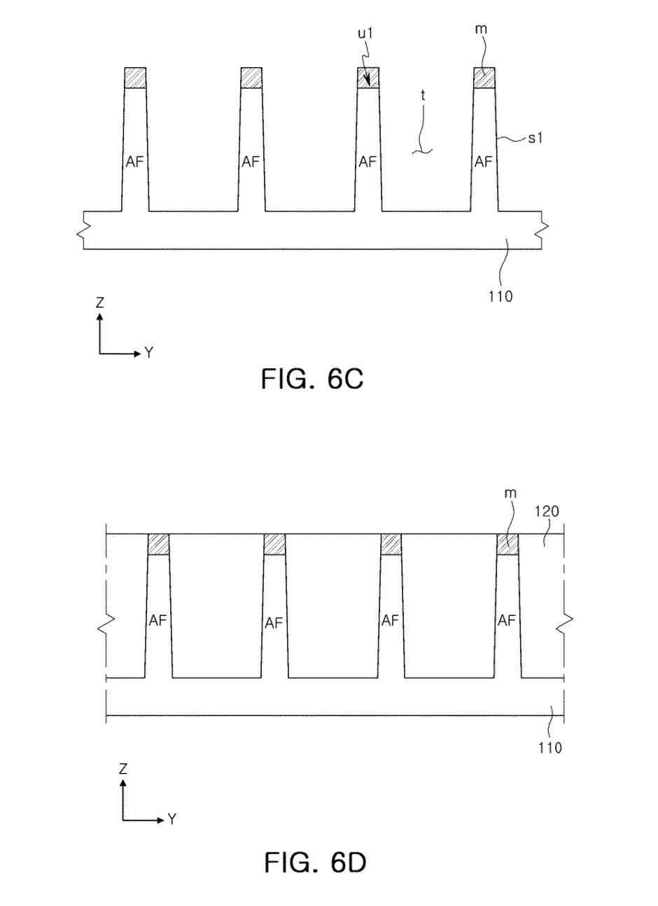

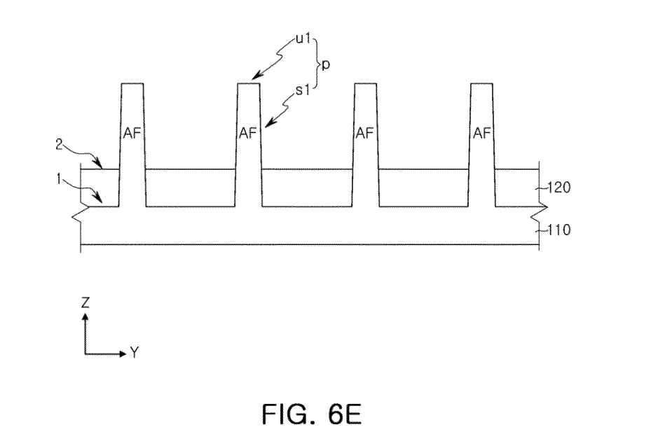

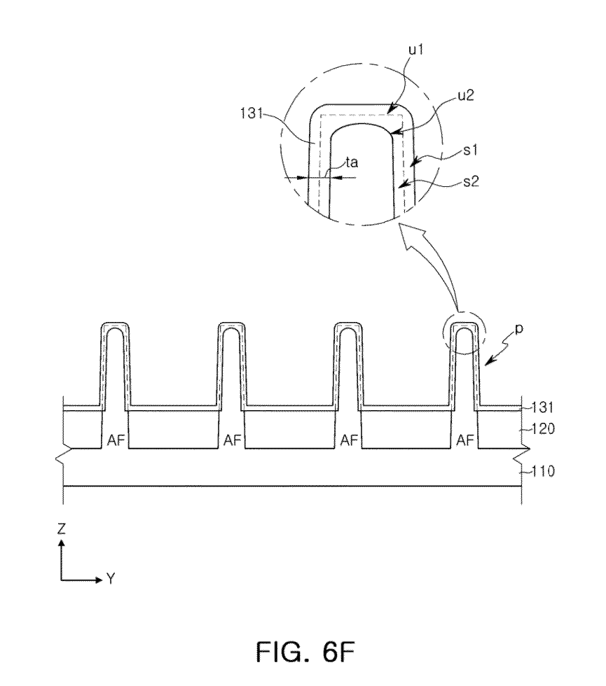

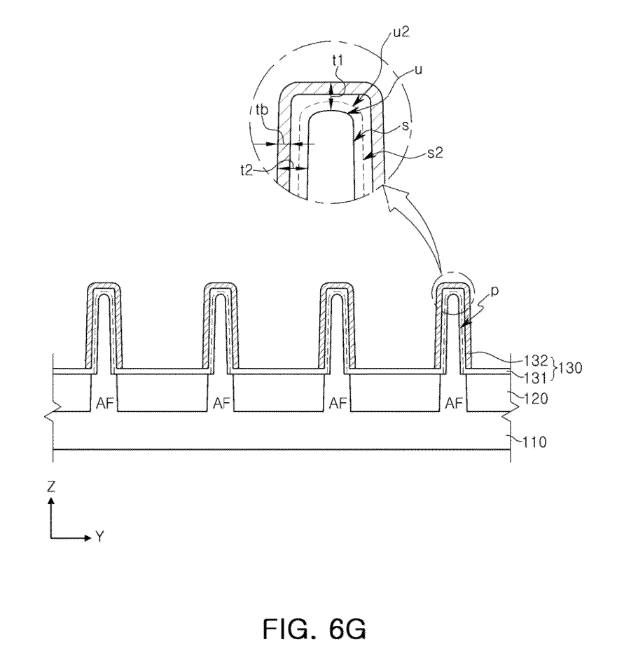

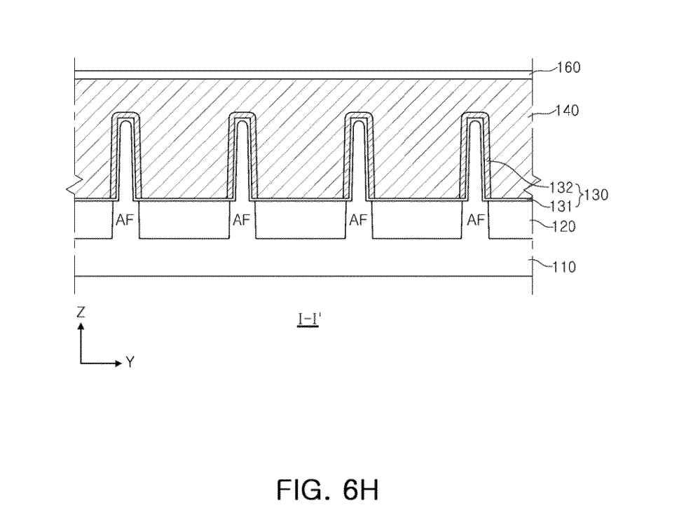

The gate insulating layer 130 may be disposed on the active fins AF and the isolation layer 120. For easy understanding, FIG. 6H, a cross-sectional view taken along line I-I′ of FIG. 1, may be referred to together.

The gate insulating layer 130 may extend in a third direction (a Y direction) to traverse the active fins AF, and cover the side walls S and the upper surfaces u of the active fins AF.

The gate insulating layer 130 may include a silicon oxide, a silicon nitride, or a silicon oxynitride. Although not limited thereto, for example, the gate insulating layer 130 may include at least one of SiO₂, SiN, SiON, SiC, SiCN, SiOCN, SiOC, SiBN, and SiBCN. Also, the gate insulating layer 130 may include a high-k dielectric material. The high-k dielectric material may include one or more of a hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but the material of the gate insulating layer 130 is not limited thereto. The gate insulating layer 130 may include a first insulating layer 131 and a second insulating layer 132 as described hereinafter.

The gate electrode 140 may be disposed on the gate insulating layer 130. The gate electrode 140 may be disposed to extend in the third direction (the Y direction) to traverse the active fins AF. In example embodiments, the gate electrode 140 may include polycrystalline silicon or doped polycrystalline silicon. However, the material of the gate electrode 140 is not limited thereto, and the gate electrode 140 may include a metal. In this case, the metal may include at least one of aluminum (Al), tungsten (W), molybdenum (Mo), and the like.

Spacers 150 may be disposed on both side walls of the gate electrode 140. The spacers 150 may include at least one of silicon oxide, silicon nitride, silicon oxynitride, and silicon oxycarbonitride, and combinations thereof. Also, the spacers 150 may be formed as a single layer or multiple layers. Although not limited thereto, according to circumstances, a gate mask layer 160 may be disposed on the gate electrode 140.

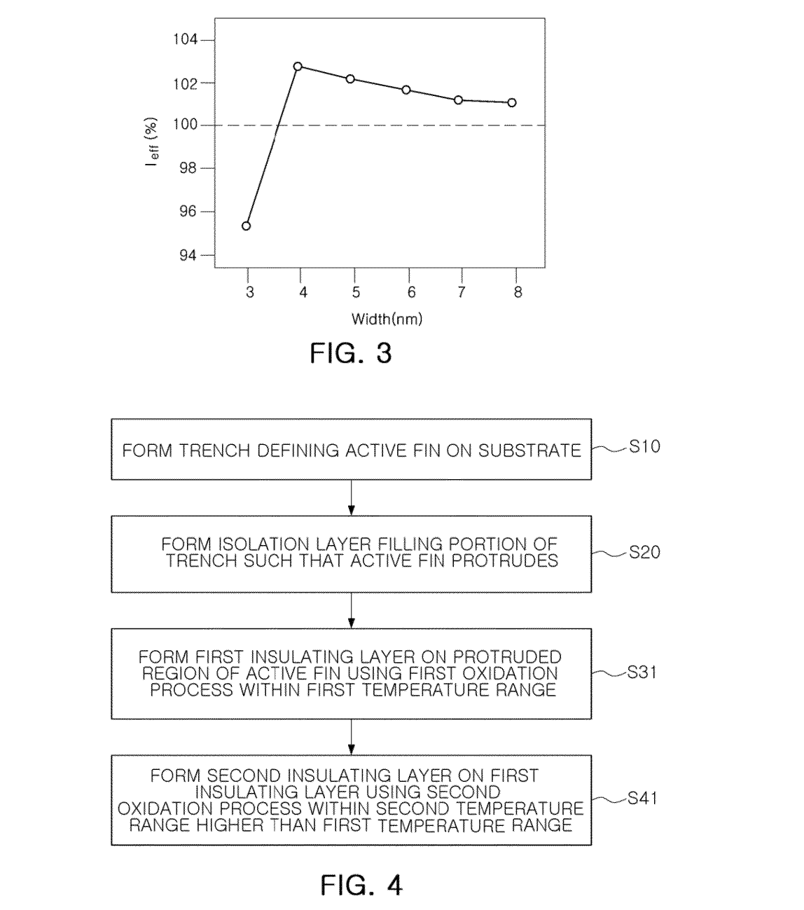

FIG. 2 is an enlarged view of a region ‘R’ of FIG. 1, specifically illustrating the active fins AF according to example embodiments. FIG. 3 is a graph illustrating variations in driving currents according to widths of active fins of a fin-shaped field effect transistor (FinFET).

Referring to FIG. 2, the active fin AF may have different widths in upper and lower portions thereof. For example, the protruded region p of the active fin AF may include a first region p1 having a side wall s above the second surface 2 of the isolation layer 120 and a second region p2 positioned on the first region p1 and having an upper surface u. The first region p1 may have a first width w1 in the third direction (the Y direction) adjacent to the second surface 2 of the isolation layer 120 and a second width w2 in the third direction (the Y direction) adjacent to the second region p2.

In example embodiments, the second region p2 may be a region defined as a top portion of the active fin AF. For example, when the upper surface u of the active fin AF is a curved surface, a section from the peak of the upper surface u to a point at which curvature of the curved surface forming the upper surface u is 0 may be defined as the top portion. The first region p1 may be defined as a region formed as the side wall s of the active fin AF, as a region excluding the second region p2 of the protruded region p of the active fin AF.

In example embodiments, the first and second widths may be widths of the active fin AF at first and second heights h1 and h2 with respect to the second surface 2 of the isolation layer 120.

Here, the first and second heights h1 and h2 are presented to provide a reference for measuring a lower width and an upper width of the active fin AF. For example, in a case where the upper surface u of the active fin AF is formed as a curved surface, the width is rapidly reduced in the first direction (the Z direction) in a region (namely, the second region p2 has a region in which the width is rapidly reduced), and here, the first and second heights h1 and h2 may provide a reference for measuring a lower width and an upper width in a state in which the region (the second region p2) in which the width is rapidly reduced is excluded.

Here, the first height h1 is 6% or less of the height ht of the active fin AF, and the second height h2 may be 85% or greater of the height ht of the active fin AF. In other words, the first height h1 may be greater than 0% of the height ht and less than or equal to 6% of the height ht. Also, the second ht may be greater than or equal to 85% of the height ht and less than a height h3. The height h3 may be less than the height ht. The height ht of the active fin AF is a height of the active fin AF protruded with respect to the second surface 2 of the isolation layer 120 and may be understood as having the same concept as the maximum height of the upper surface u. Although not limited thereto, the height ht of the active fin AF, namely, the maximum height of the upper surface u, may be 35 nm or greater, for example, in a range of 35 nm to 100 nm.

For the convenience of measurement, with respect to the second surface 2 of the isolation layer 120 and the height (namely, the maximum height ht of the upper surface u), the first height h1 may be at a level higher than the second surface 2 of the isolation layer 120 by a desired (and/or alternatively predetermined) numerical value (a), for example, by 2 nm. The second height h2 may be at a level lower than the height ht of the active fin AF by a desired (and/or alternatively predetermined) numerical value (b), for example, by 5 nm.

In general, in order to highly integrate a semiconductor device, the width of the active fin AF needs to be reduced. For example, in a Fin-FET of 10 nm level or lower, the first width w1 of the active fin AF may be 10 nm or less. However, on the other hand, the width of the active fin AF needs to be secured to have an appropriate range. In detail, in the Fin-FET, when the width of the active fin AF is changed, a size of a channel is changed, which affects a threshold voltage and a driving current. In particular, referring to FIG. 3, when the width of the active fin AF is reduced to 4 nm or less, a driving current I_{eff} tends to be rapidly reduced due to a quantum confinement effect.

Thus, although not limited thereto, the active fin AF may be formed to have as narrow a width as possible, but not smaller than 4 nm.

In general, the active fin AF tends to decrease in width as it protrudes from the substrate 110 in the first direction (the Z direction). This is because of the tendency that, when a trench for defining the active fin AF is formed, a width of the trench decreases as the trench is etched downwardly (please refer to FIG. 6C), and in addition, after the active fin AF is formed, when an oxidation process is performed to cure etching damage of the active fin AF or when an oxidation process is performed to form the gate insulating layer 130 on the active fin AF, a material (e.g., silicon) forming the active fin AF is considerably consumed in the upper portion of the active fin AF. Thus, it is important to secure the upper width of the active fin AF to a desired (and/or alternatively predetermined) level or higher, while reducing the lower width of the active fin AF as small as possible.

Referring to FIG. 2, in the active fin AF according to example embodiments, the second width w2 may be 60% or greater than the first width w1. Although not limited thereto, the second width may be 60% to 100% of the first width w1, and possibly, 60% to 75% of the first width w1. For example, the semiconductor device 100 according to example embodiments may be a logic device of 10 nm level or lower, and in this case, if the first width w1 of the active fin AF is about 10 nm or greater, the second width w2 may be about 6 nm or greater.

This is not realized in the related art semiconductor device. Unlike a related art active fin shape in which a ratio of the second width w2 to the first width w1 is substantially about 40% to 50%, in the semiconductor device 100 according to example embodiments, the active fin having a shape almost close to a rectangular shape is formed by using the manufacturing process described hereinafter with reference to FIGS. 6A through 6H, which was not possible in the related art. Here, the side wall s of the active fin AF may have an angle θ1 ranging from 86 degrees to 90 degrees with respect to the second surface 2 of the isolation layer 120.

The active fin AF may have a region in which the width increases in a direction toward the substrate 110 from the upper surface u. This may be understood that as the loss of the active fin AF increases, the upper corners are rounded.

Namely, the active fin AF has the upper surface u as a curved surface formed as the corners are gently rounded, and the upper surface u of the active fin AF according to example embodiments may have a radius of curvature (r) equal to or greater than 3.5 nm. In detail, the radius of curvature (r) of the upper surface u may range from 3.5 nm to 5 nm. When the radius of curvature (r) of the upper surface u is large, it may be understood that the upper width of the active fin AF is rapidly reduced, and the numerical value range of the radium of curvature (r) was not realized in an active fin AF having a first width equal to or smaller than 10 nm in the related art. For example, the numerical value range of example embodiments is considered to be significantly greater than a general numerical value, which ranges from 1.5 nm to 2.5 nm, of a radius of curvature of the upper surface u of the active fin AF.

The width of the active fin AF increases in a direction toward the lower side (the direction toward the substrate 110) from the peak of upper surface of the active fin AF and the height h3 at a point where the width w3 has 4 nm may be a height equal to 97% or greater of the height ht of the active fin AF and less than the height h1.

In example embodiments, the difference (da) between the height h3 at which the width w3 of the active fin AF is 4 nm and the height ht of the active fin AF may be 0.9 nm or less. In other words, the height h3 at which the width w3 of the active fin AF is 4 nm may be at a level equal to or smaller than 0.9 nm from the height ht of the active fin AF. Specifically, the height h3 may be 0.3 nm to 0.9 nm lower than the height ht of the active fin AF. This is considered as a significantly improved numerical value range, compared with the related art numerical value range from 2 nm to 3.6 nm.

According to example embodiments, the active fin AF, in which the upper width thereof has a sufficiently large width in order to reduce an influence of a short channel effect, may be secured.

In addition, the active fin AF may have a shape in which a leaning phenomenon is reduced. In detail, the active fin AF may include an buried region p′ positioned at a level lower than the second surface 2 of the isolation layer 120 and a protruded region p positioned at a level higher than the second surface 2 of the isolation layer 120. Here, when a central axis traversing the center of the width of the buried region p′ and the protruded region p are defined, an angle θ2 between the central axis c1 of the buried region p′ and a central axis c2 of the protruded region p may be 180±3°. Namely, a difference in angle between the central axis c1 of the buried region p′ and the central axis c2 of the protruded region p may be 3° or less (e.g., in a rage of 0° to 3°).

According to example embodiments, since the upper width is sufficiently secured, while the lower width of the active fin AF is set to be narrow, to highly integrate the semiconductor device 100, the semiconductor device 100 in which a reduction in a driving current due to a short channel effect is alleviated may be obtained.

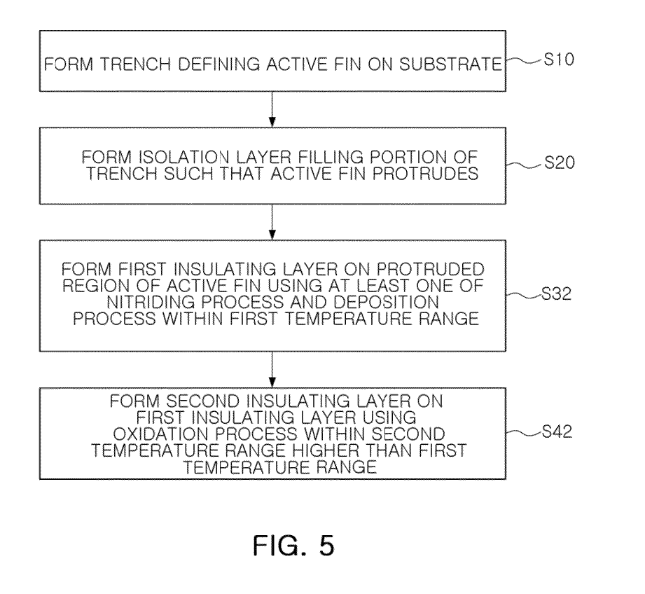

Hereinafter, the process of manufacturing the semiconductor device 100 according to example embodiments will be described in detail with reference to FIGS. 4, 5, and 6A through 6H.

Referring to FIG. 4, the method for manufacturing a semiconductor device 100 according to example embodiments may include an operation (S10) of forming a trench defining at least one active fin on a substrate, an operation (S20) of forming an isolation layer filling a portion of the trench such that the active fin protrudes, and operations (S31 and S41) of forming first and second insulating layers by using first and second oxidation processes within first and second temperature ranges, respectively.

The process of forming the first insulating layer may use a nitration process or a deposition process, in addition to the oxidation process. For example, the process of forming the first insulating layer may include an operation (S32) of forming a first insulating layer on the active fin by using at least one of a nitration process and a deposition process within a first temperature range and an operation (S42) of forming a second insulating layer on the first insulating layer by using an oxidation process within a second temperature range higher than the first temperature range.

Hereinafter, each process will be described in detail with reference to FIGS. 6A through 6H.

FIGS. 6A through 6H are views schematically illustrating processes of a method for manufacturing the semiconductor device of FIG. 1 according to example embodiments of inventive concepts, specifically, cross-sectional views taken along line I-I′ of FIG. 1.

Referring to FIG. 6A, a mask layer m′ and a sacrificial pattern layer 10 are sequentially formed on the substrate 110, and a preliminary spacer layer 20′ may be formed on the mask layer m′ and the sacrificial pattern layer 10.

The mask layer m′ may be a hard mask layer. For example, the mask layer m′ may be formed of at least one of a silicon containing material such as a silicon oxide, a silicon nitride, a silicon oxynitride, or a polysilicon, a hydrocarbon compound such as an amorphous carbon layer (ACL), or a spin-on hardmask (SOH), and a metal. Also, the mask layer m′ may have a multilayer structure in which a silicon oxide and a silicon nitride are sequentially stacked. The size of the sacrificial pattern layer 10 may be determined in consideration of a space between active fins AF intended to be formed.

The preliminary spacer layer 20′ may be formed to have a substantially uniform thickness on an upper surface of the substrate 110 on which the sacrificial pattern layer 10 is formed. The preliminary spacer layer 20′ and the sacrificial pattern layer 10 may be formed of materials having etch selectivity. For example, the preliminary spacer layer 20′ and the sacrificial pattern layer 10 may be formed of at least one of a silicon containing material such as a silicon oxide, a silicon nitride, a silicon oxynitride, or a polysilicon, a hydrocarbon compound such as a photoresist, an amorphous carbon layer (ACL), or a spin-on hardmask (SOH), and a metal. In example embodiments, the preliminary spacer layer 20′ may be formed of polysilicon, and the sacrificial pattern layer 10 may be formed of a hydrocarbon compound. The preliminary spacer layer 20′ may be formed through a process such as atomic layer deposition (ALD), chemical vapor deposition (CVD), or spin coating, and according to materials, a baking process or a curing process may be additionally performed.

Thereafter, as illustrated in FIG. 6B, a mask pattern layer m for forming an active fin AF may be formed by using an etch process.

First, the preliminary spacer layer 20′ may be etched through an anisotropic etching process until when the mask layer m′ is exposed, thus forming spacer layers 20. As the anisotropic etching process, reactive ion etching (RIE) may be used. The spacer layers 20 may be used as etch masks in patterning the mask layer m′. Thus, widths (Y direction) of the spacer layers 20 on the side walls of the sacrificial pattern layer 10 may be determined in consideration of the width of active fins AF intended to be formed in a follow-up process. The widths of the spacer layers 20 may be appropriately adjusted depending on thickness and etching conditions of the preliminary spacer layer 20′. Although not limited thereto, the widths of the spacer layers 20 may be subsequently equal.

Subsequently, the sacrificial pattern layer 10 may be removed to leave only the spacer layers 20. The removing of the sacrificial pattern layer 10 may include a selective etching process for minimizing etching of the spacer layers 20.

Thereafter, the mask layer m′ may be etched using the spacer layers 20 as etching masks to form the mask pattern layer m.

Thereafter, as illustrated in FIG. 6C, the substrate 110 may be etched using the etching mask pattern layers m as etch masks to form trenches t defining active fins AF in operation S10.

As the etching process, an RIE process may be used as an anisotropic etching process.

As regions of the substrate 110 become away from the mask pattern layer m, a time for which the regions are exposed to the etching reaction decreases, and thus, the widths of the trenches t decrease downwardly. Accordingly, the angle of the side walls s1 of the active fins AF has a desired (and/or alternatively predetermined) value, rather than being perpendicular. Namely, it may be understood that the widths of the active fins AF increase downwardly. In the current stage, upper surfaces u1 of the active fins AF are contiguous with the mask pattern layers m, having a horizontal plane.

While the etching process is being performed, the surface of the substrate 110 and the sides s1 of the active fins AF may be etch-damaged due to collisions of ionized particles, causing a trap site or a lattice defect on the surface of the substrate 110 and on the sides s1 of the active fins AF.

Thereafter, as illustrated in FIGS. 6D and 6E, an isolation layer 120 may be formed to fill portions of the trenches t such that the active fins AF protrude from the substrate 110.

First, as illustrated in FIG. 6D, an isolation layer 120 may be formed to fill the trenches between the active fins AF. Although not limited thereto, the isolation layer 120 may be formed of at least one of a boron-phosphor silicate glass (BPSG), a high density plasma (HDP) oxide, a flowable oxide (FOX), a tonen silazene (TOSZ), a spin-on-glass (SOG), an undoped silica glass (USG), a tetraethyl ortho silicate (TEOS), and a low temperature oxide (LTO), having excellent filling characteristics.

Subsequently, as illustrated in FIG. 6E, the isolation layer 120 may be planarized to expose upper surfaces of the mask pattern layers m, and etched such that portions of the active fins AF protrude. The planarizing of the isolation layer 120 may be a chemical mechanical polishing process.

After the isolation layer 120 is planarized, the mask pattern layers m may be first removed by using a selective ion etching process. For example, in a case where the mask pattern layers m are formed of a silicon nitride film and the isolation layer 120 is formed of a silicon oxide, the mask pattern layers m may be removed using a phosphoric acid (H₃PO₄).

Thereafter, portions of the isolation layer 105 may be removed to using dry etching or wet etching such that the active fins AF have regions protruding above the isolation layer 120. However, without limited thereto, the isolation layer 120 may be first etched, and thereafter, the mask pattern layers m may be removed.

When the process of etching the isolation layer 120 is completed, the isolation layer 120 has a first surface 1 contiguous with the substrate 110 and a second surface 2 opposing the first surface 1, and the active fins AF have regions p protruding above the second surface 2 of the isolation layer 120. The protruded regions p may include a side wall s1 and an upper surface u1. Here, the side wall s1 and the upper surface u1 of each active fin may be damaged through the etching process of the isolation layer 120.

Thereafter, as illustrated in FIG. 6F, in order to cure etch-damage of the side wall s1 and the upper surface u1 of the active fin AF, a first insulating layer 131 may be formed on the protruded side wall s1 and the upper surface u1 of the active fin AF in operations S31 and S32.

The first insulating layer 131 may include at least one of SiO₂, SiN, SiON, SiC, SiCN, SiOCN, SiOC, SiBN, SiBCN, and combinations thereof.

In some cases, before the formation of the first insulating layer 131, a cleaning process may be performed in order to remove contaminants generated during the etching process of the isolation layer 120 or a native oxide on the active fin AF.

In example embodiments, the first insulating layer 131 may be formed through a first oxidation process within a first temperature range. In this case, the first insulating layer 131 may include a silicon oxide formed as the protruded region p of the active fin AF is oxidized. Namely, the etch-damage may be cured as the etch-damaged surface of the active fin AF is oxidized.

Meanwhile, as the oxidization process is in progress, the material (for example, silicon (Si)) forming the active fin AF may be consumed from the surface of the active fin AF. Thus, the upper corners of the active fin AF may be rounded and the width of the active fin AF may be reduced. The upper surface u1 which has been flat prior to the oxidation process may be changed to an upper surface u2 having a desired (and/or alternatively predetermined) curvature.

Here, when a high temperature oxidation process is performed on the active fin AF, rapid oxidation be made, making it difficult for the active fin AF to have a sufficient width, and in particular, when the oxidation is actively performed in the upper surface u1, it may be difficult to obtain an upper width having an intended size.

In addition, it may be difficult to maintain uniform thickness of the insulating layer, and as the active fin AF is exposed to high temperatures, the protruded regions may lean.

In consideration of this, in example embodiments, a first temperature range for the first oxidation process may be low temperatures equal to or lower than 800° C. (e.g., in a range of 200° C. to 800° C.). In this case, the first oxidation process may be performed at low temperatures, and may be a plasma radical oxidation process. Although not limited thereto, the plasma radical oxidation process may be performed using an inert gas (for example, argon (Ar), xenon (Xe), etc.), an oxygen-containing gas (for example, O₂, O₃, H₂O, No, N₂O, etc.) and a hydrogen (H₂) gas, and the like, at temperatures ranging from about 400° C. to 600° C. and under pressure ranging from tens of mTorr to a few Torr, for example, from 10 mTorr to 9 Torr.

When the plasma radical oxidation process performed at low temperatures is used, since the process temperature is low, the surface of the active fin AF is mainly oxidized and rapid oxidation of the upper surface u1 of the active fin AF may be limited and/or prevented. Thus, the upper surface u2 having a radius of curvature with a sufficient size and the active fin AF having an upper width within an appropriate range may be obtained.

Also, since the oxidation process performed at low temperatures is used, an interface between the first insulating layer 131 and the active fin AF may be formed to be uniform and leaning of the active fin AF may be reduced.

In order to form the first insulating layer 131, a nitriding process performed within a first temperature range, as well as the oxidation process, may be used.

The nitriding process may be a plasma radical nitriding process performed at a first temperature range, for example, at low temperatures equal to or lower than 800° C. (e.g., in a range of 200° C. to 800° C.). In this case, the first insulating layer 131 may include a silicon nitride formed as the protruded region of the active fin AF is nitrated.

Also, in order to form the first insulating layer 131, a deposition process performed within the first temperature range, as well as the oxidation and nitriding process, may also be used. For example, at least one of a silicon oxide, a silicon nitride, and a silicon oxynitride may be deposited on the protruded region p of the active fin AF by using at least one of a chemical vapor deposition (CVD) process and an atomic layer deposition (ALD) process. In a case in which a silicon oxide film is deposited by using the CVD or ALD process, for example, a source gas such as SiH₄, O₂, O₃, N₂, or TEOS may be used within the first temperature range and at pressure ranging from tens of mTorr to a few Torr, for example, from 10 mTorr to 9 Torr.

In a case in which a silicon nitride film is deposited by using the CVD or ALD process, for example, a source gas such as SiH₄, NH₃, or dichlorosilane (DCS) may be used within the first temperature range and at pressure ranging from tens of mTorr to a few Torr, for example, from 10 mTorr to 9 Torr.

In example embodiments, a thickness ta of the first insulating layer 131 may need to be formed within an appropriate range. If the thickness ta of the first insulating layer 131 is too small, it may be insufficient to properly cure the etch-damaged active fin AF, and it may be difficult for the first insulating layer 131 to effectively serve to limit and/or prevent leaning of the active fin AF as described hereinafter. However, since the first insulating layer 131 is oxidize, nitrated, or deposited at relatively low temperatures, time dependent dielectric breakdown characteristics thereof are relative low, compared with an insulating layer formed at high temperatures, and thus, there is no need to form the first insulating layer 131 to be thicker than necessary. For example, the first insulating layer 131 may be formed to have the thickness to ranging from 20 Å to 35 Å.

In general, after the insulating layer (e.g., the first insulating layer 131) formed to cure the etch-damaged active fin AF, the insulating layer is removed through a wet etching process using a buffer oxide etchant (BOE) solution. However, in example embodiments, the first insulating layer 131 is not removed and a second insulating layer 132 may be continuously formed on the first insulating layer 131 in a follow-up process. Namely, the first insulating layer 131 formed to cure the etch damage, as well as the second insulating layer 132, may be used as a gate insulating layer 130.

In detail, as illustrated in FIG. 6G, the second insulating layer 132 may be formed on the first insulating layer 131 to cover the first insulting layer 131 in operations S41 and S42. The second insulating layer 132 may include, for example, a silicon oxide. The second insulating layer 132 may be formed of the same material as that of the first insulating layer 131. However, the material of the first insulating layer 131 and the second insulating layers 132 is not limited thereto and the first second insulating layer 131 and the second insulating layer 132 may be formed of different materials.

In example embodiments, the second insulating layer 132 may be formed by using a second oxidation process within a second temperature range.

The second temperature range within which the second oxidation process is performed may be high temperatures equal to or higher than 800° C. For example, the second oxidation process may include a thermal radical oxidation process. Although not limited thereto, the thermal radical oxidation process may be performed using a gas (for example, O₂, O₃, etc.), a hydrogen (H₂) gas, and the like, under temperatures ranging from about 800° C. to 1050° C. at pressure ranging from tens of mTorr to a few Torr, for example, from 10 mTorr to 9 Torr.

In this case, the second insulating layer 132 is grown at high temperatures, thus having excellent Time-dependent dielectric breakdown (TDDB) characteristics. The second insulating layer 132 may be formed to have a thickness tb greater than that of the first insulating layer 131, and for example, the thickness of the second insulating layer 132 may be appropriately determined within a range from 35 Å to 45 Å. However, the thickness of the second insulating layer 132 is not limited thereto.

As the second oxidation process is performed to form the second insulating layer 132, silicon (Si) may be consumed from the surface and the interior of the active fin AF. Thus, the upper corners of the active fin AF may be further rounded and the width of the active fin AF may be reduced. In detail, compared with the active fin AF prior to the formation of the second insulating layer 132, with the second insulating layer 132 formed, the width of the active fin AF or the height ht of the active fin AF may be reduced.

However, unlike the case where a high temperature oxidation process is directly performed on the surface of the active fin AF in a state in which the insulating layer is removed, since the oxidation process is performed on the active fin AF with the insulating layer 131 formed thereon, silicon loss of the active fin AF may be reduced, and thus, a rapid reduction in the width of the active fin AF may be limited and/or prevented. In particular, the active fin AF having the upper width having a sufficient size may be easily formed.

For example, referring to FIG. 6G together with FIG. 2, after the formation of the second insulating layer 132, the active fin AF has a first width w1 and the second width w2, and the second width w2 may be 60% or greater of the first width w1, for example, in a range of 60% to 100% of the first width w1.

Also, the upper surface u of the active fin AF is rounded during the process of forming the first and second insulating layers 131 and 132, and accordingly, the active fin AF has a region with a width increasing in a direction toward the substrate 110. The height h3 at which the width w3 of the active fin AF is 4 nm may have a level lower by 0.9 nm from the height ht of the upper surface u of the active fin AF. Although not limited thereto, the upper surface u of the active fin AF may have a radius of curvature equal to or greater than 3.5 nm.

In addition, according to the manufacturing method of example embodiments, leaning of the active fin AF may be limited and/or prevented. In detail, when the second oxidation process is performed in a state in which the first insulating layer 131 is removed, the region p of the active fin AF protruding from the isolation layer may be affected by high temperatures so as to lean at a desired (and/or alternatively predetermined) angle. For example, when the active fin AF is divided into the buried region p′ positioned at a level lower than the second surface 2 of the isolation layer 120 and the protruded region p positioned at a level higher than the second surface 2, the central axis c2 of the protruded region p and the central axis c1 of the buried region p′ may be different in desired (and/or alternatively predetermined) angle. This may be a factor affecting a threshold voltage and a driving current.

Meanwhile, in example embodiments, since the active fin AF is covered by the first insulating layer 131 during the second oxidation process performed at high temperatures, even though it is exposed to high temperatures, leaning of the second region may be limited and/or prevented. For example, according to example embodiments, a difference in angle between the central axis c1 of the buried region p′ of the active fin AF and the central axis c2 of the protruded region p of the active fin AF may be 3° or less (e.g., in a range of 0° to 3°).

According to example embodiments, the first insulating layer 131 formed to cure etch-damaged active fin AF is not removed and the second insulating layer 132 is formed on the first insulating layer 131 in a follow-up process, and the first and second insulating layers 131 and 132 may serve as a gate insulating layer 130.

In this case, as described above, both the first insulating layer 131, having excellent interface characteristics with the active fin AF, and the second insulating layer 132, having excellent TDDB characteristics, may be used as the gate insulating layer 130 and resistance is reduced and mobility of carriers is enhanced. In addition, since the upper width of the active fin AF is secured within an appropriate range and leaning of the active fin AF is limited and/or prevented, when the semiconductor device is manufactured, a threshold voltage and a driving current of a transistor may be accurately controlled.

In addition, the first insulating layer, which is formed at low temperatures and thus may be controlled to have a relatively uniform thickness, is used, a thickness of the gate insulating layer 130 (the sum of the thicknesses of the first and second insulating layers 131 and 132) may be uniform.

In detail, the gate insulating layer 130 may have the thickness t1 on the upper surface u of the active pattern AF which is 96% to 106% of the thickness t2 on the side wall s of the active fin AF. Thus, the thicknesses of the gate insulating layer 130 disposed on the upper surface u and the side walls may be substantially 1:1 in a numerical value range.

In some example embodiments, the second insulating layer 132 may be directly formed on the active fin AF at high temperatures after the removing of the first insulating layer 131 formed to cure the etch-damaged active fin AF, so the thickness of the gate insulating layer 130 disposed on the upper surface u of the active fin AF is 75% to 83% of the thickness of the gate insulating layer 130 disposed on the side wall s of the active fin AF.

Thereafter, as illustrated in FIG. 6H, a gate electrode 140 may be formed on the second insulating layer 132 and a gate mask layer 160 may be formed on the gate electrode 140. Accordingly, the semiconductor device 100 the same as that illustrated in FIG. 1 may be obtained.

The gate electrode 140 may include, for example, polycrystalline silicon or doped polycrystalline silicon, but the material of the gate electrode 140 is not limited thereto and the gate electrode 140 may include a metal.

As illustrated in FIG. 1, the gate electrode 140 may be disposed to traverse the active fins AF. Impurity regions im may be formed in regions of the active fins AF not covered by the gate electrode 140 through ion implantation process, or the like, so as to be provided as source and drain regions.

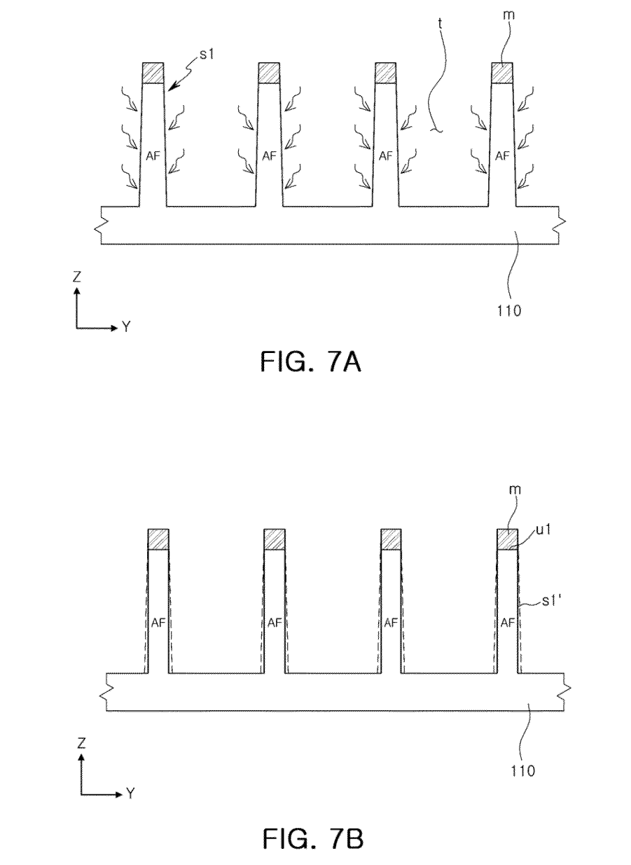

FIGS. 7A and 7B are cross-sectional views sequentially illustrating processes of a method for manufacturing a semiconductor device according to Example embodiments of inventive concepts.

Example embodiments may be understood as a non-limiting example in which a process of surface-treating the side wall of the active fins AF is further included in the manufacturing method described above with reference to FIGS. 6A through 6H.

FIG. 7A is a cross-sectional view illustrating a state prior to the operations S31 and S32 of forming the first insulating layer 131 after the operation S10 of forming the trenches t defining the active fins AF. This state may be understood as a state in which formation of the trenches t has been completed as illustrated in FIG. 6C.

As illustrated in FIG. 7A, the trench t has a width decreasing in a downward direction, and thus the angle of the side wall s1 of the active fin AF has a desired (and/or alternatively predetermined) value, rather than being perpendicular, and the width of the active fin AF may increase in the downward direction. In addition, the side wall s1 of the active fin AF may have roughness.

Referring to FIG. 7A, before the formation of the first insulating layer 131, an operation of surface-treating the side wall s1 of the active fin AF may be further provided. The operation of surface-treating may be an operation of surface-treating the active fin AF with plasma of at least one of hydrogen and an inert gas at a temperature equal to or lower than 700° C.

The inert gas may be helium (He), neon (Ne), argon (Ar), krypton (Kr), xenon (Xe), radon (Rn), and the like. Pressure of the gas may be 999 Torr or below (e.g., greater than 0 Torr and less than or equal to 999 Torr), and plasma generation power may range from 1 kW to 5 KW. For example, the plasma generation power may range from 2 KW to 4 KW. A plasma generation method is not particularly limited and may be, for example, direct plasma, remote plasma, radiofrequency plasma, microwave plasma, inductively coupled plasma, capacitively coupled plasma, or an electron cyclotron resonance plasma scheme. The surface treatment operation may be performed for 10 seconds to 999 seconds, but is not limited thereto.

The surface treatment operation may be performed at low temperatures equal to or lower than 700° C. When the surface treatment operation is performed at low temperatures, thermal energy is transmitted only to the surface of the active fin AF, causing the Oswald ripening on the surface of the active fin AF. The Oswald ripening refers to a phenomenon in which small particles move toward large particles due to a difference in surface energy at the same temperature to result in that small particles disappear as being absorbed into large particles and the large particles increase. Namely, due to the Oswald ripening, small particles providing roughness disappear, and thereby improving the surface roughness of the protruded region p. For example, after the surface treatment is performed, as illustrated in FIG. 7B, the side wall s1′ of the active fin AF may have mean square roughness equal to or less than 2 nm. In addition, due to the Oswald ripening effect, the side wall s1′ of the active fin AF may be changed to be substantially perpendicular. Namely, when the isolation layer 120 is formed in a follow-up process, the side wall s may have an angle θ1 ranging from 85° to 90° with respect to the second surface 2 of the isolation layer 120.

Here, more effective gas may be hydrogen (H₂) gas, and gas pressure may be 1 Torr or less (e.g., 0 Torr to less than or equal to 1 Torr). If the surface treatment operation is performed at high temperatures higher than 700° C., a chemical bond state of the active fin AF may be affected to be excessively changed in shape. Thus, the surface treatment operation may be performed at a temperature equal to or lower than 700° C. For example, the surface treatment operation may be performed at temperatures ranging from 300° C. to 500° C. Meanwhile, besides the hydrogen gas, a helium (He) gas may also be used, and in this case, gas pressure may be 5 Torr to 25 Torr.

It is described that the surface treatment operation is performed before the formation of the isolation layer 120, but example embodiments are not limited thereto. The surface treatment operation may be performed after the trenches and the isolation layer 120 are formed and before the first insulating layer 131 is formed.

Meanwhile, when the side wall s1′ of the active fin AF has the substantially perpendicular slope, the side wall s1′ may have a plane (110) in which dangling bond is induced, as a crystal plane. In this case, it may be difficult to aptly form an insulating layer on the active fin AF, so negative bias temperature instability (NBTI) characteristics of a transistor may be degraded. However, in example embodiments, since the first insulating layer 131 may be formed by using the low temperature plasma oxidation scheme rarely dependent on a plane orientation, and the first insulating layer 131 is not removed but used as the gate insulating layer 130 in a follow-up process, and thus, the insulating layer having a relatively uniform thickness may be formed.

Thereafter, the semiconductor device as illustrated in FIG. 1 may be obtained through the processes described above with reference to FIGS. 6D through 6H.

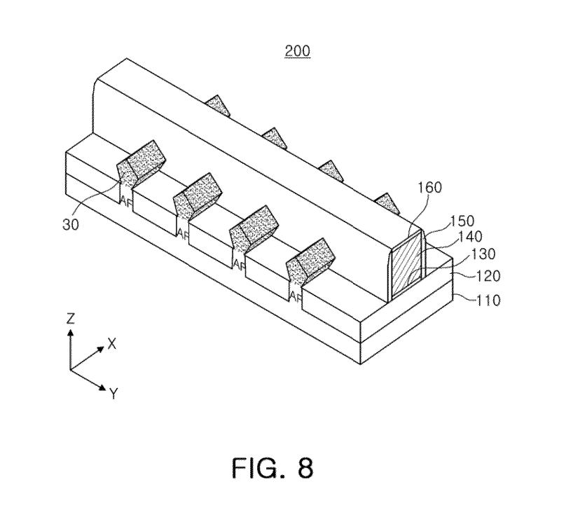

FIG. 8 is a perspective view schematically illustrating a semiconductor device 200 according to Example embodiments of inventive concepts.

Referring to FIG. 8, in example embodiments, the semiconductor device 200 includes a substrate 110, and an isolation layer 120 and at least one active fin AF disposed on the substrate 110. A gate insulating layer 130 and a gate electrode 140 may be disposed on the at least one active fin (AF). Hereinafter, the contents identical to those of the previous described may be omitted, and different components will be largely described.

In example embodiments, the semiconductor device 200 may further include source/drain stressors 30 disposed on the active fins AF. The source drain stressors 30 may be formed by removing portions of the active fins AF exposed at both sides of the gate electrode 140 to form recesses, and performing an epitaxial process on the recessed active fins AF. An outer circumferential surface of each source/drain stressor 30 may have a polygonal shape (for example, a pentagonal shape, a hexagonal shape, and the like).

The source/drain stressor 30 may include a p-type impurity when the semiconductor device 200 is a PMOS transistor. In this case, the source/drain stressor 30 may include a compressive stress material. The compressive stress material may be, for example, SiGe as a material having a lattice constant greater than that of silicon (Si). In this inventive concept, the compressive stress material may be used as a material applying compressive stress to a peripheral region thereof, for example, a channel region.

Alternatively, the source/drain stressor 30 may include an n-type impurity when the semiconductor device 200 is an NMOS transistor. In this case, the source/drain stressor 30 may include a tensile stress material. The tensile stress material may be, for example, silicon (Si) or SiC as a material having a lattice constant smaller than that of silicon (Si). In this inventive concept, the tensile stress material may be used as a material applying tensile stress to a peripheral region thereof, for example, a channel region.

When the source/drain stressor 30 includes a tensile stress material or a compressive stress material, carrier mobility may be enhanced and a driving current of a transistor may be increased.

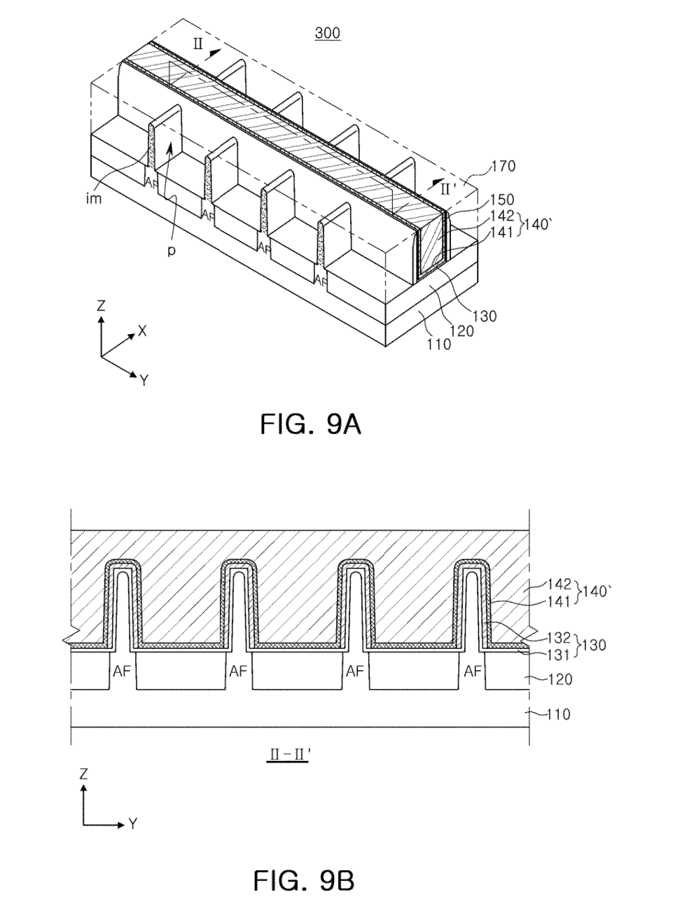

FIG. 9A is a perspective view illustrating a semiconductor device 300 according to example embodiments of inventive concepts, and FIG. 9B is a cross-sectional view taken along line II-II′ of FIG. 9A.

Referring to FIGS. 9A and 9B, the semiconductor device 300 includes a substrate 110, an isolation layer 120, and at least one active fin AF. A gate insulating layer 130 and a metal gate electrode 140′ may be disposed on the active fins AF. The gate insulating layer 130 may include a first insulating layer 131 and a second insulating layer 132 disposed on the first insulating layer 131.

According to example embodiments, the gate insulating layer 130 may further include a high-k gate insulating layer. The high-k gate insulating layer may include an insulating material having permittivity higher than that of a silicon oxide layer, and may include, for example, a tantalum oxide layer, a titanium oxide layer, a hafnium oxide layer, a zirconium oxide layer, an aluminum oxide layer, an yttrium oxide layer, a niobium oxide layer, a hafnium silicate, a zirconium silicate, and/or combinations thereof.

The metal gate electrode 140′ may be disposed on the gate insulating layer 130. The metal gate electrode 140′ may include a first metal layer 141 and a second metal layer 142 disposed on the first metal layer 141. The first metal layer 141 may serve to adjust a work function and the second metal layer 142 may serve to fill a space formed by the first metal layer 141. The first metal layer 141 may serve as a diffusion barrier with respect to a metal forming the second metal layer 142.

Although not limited thereto, the first metal layer 141 may include at least one of metal nitrides such as TiN, TaN, and WN, or TiC and TaC. The second metal layer 142 may be formed of at least one of aluminum (Al), tungsten (W), and molybdenum (Mo).

In example embodiments, the semiconductor device 300 may further include an interlayer insulating layer 170 covering at least portions of the isolation layer 120 and the metal gate electrode 140′. Although not limited thereto, the interlayer insulating layer 170 may include, for example, a low-k dielectric material, an oxide, a nitride, and/or an oxynitride. The low-k dielectric material may include, for example, a flowable oxide (FOX), tonen silazene (TOSZ), undoped silica glass (USG), borosilica glass (BSG), phosphosilaca glass (PSG), borophosphosilica glass (BPSG), plasma enhanced tetraethylortho silicate (PETEOS), fluoride silicate glass (FSG), high density plasma (HDP) oxide, plasma enhanced oxide (PEOX), flowable CVD (FCVD), or combinations thereof.

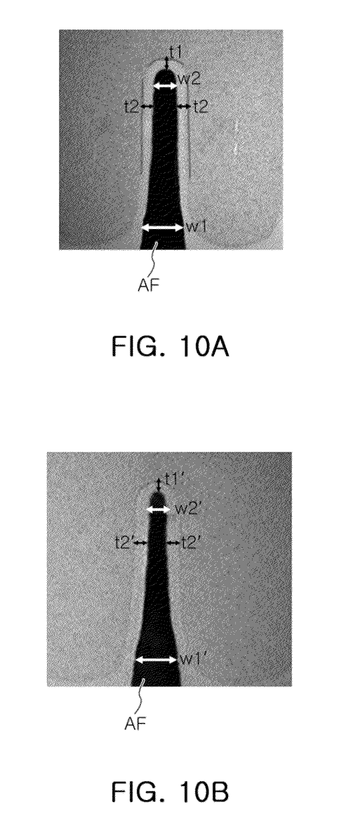

FIGS. 10A and 10B are comparative photographs illustrating shapes of active fins of a semiconductor device according to example embodiments of inventive concepts.

Specifically, FIG. 10A is a photograph illustrating a cross-section of an active fin AF formed by using the manufacturing method according to example embodiments of inventive concepts. As for the active fin AF, after a trench defining an active fin AF is formed on the substrate 110, the active fin AF was surface-treated with low temperature plasma, the isolation layer 120 was formed, and the first and second insulating layers 131 and 132 were formed by using first and second oxidation processes within first and second temperature ranges, respectively.

In contrast, as for the active fin AF illustrated in FIG. 10B, a trench defining an active fin AF and the isolation layer 120 were formed on the substrate 110, the first insulating layer 131 was formed to cure the etch-damaged active fin AF, the first insulating layer 131 was removed, and thereafter, the second insulating layer 132, which is to serve as the gate insulating layer 130, is formed on the active fin AF.

Referring to FIGS. 10A and 10B, in the active fin AF illustrated in FIG. 10A, a second width w2 was not significantly reduced with respect to a first width w1 and the upper surface u having a radius of curvature having a sufficient size was secured, compared with the active fin AF having a first width w1′ and second width w2′ illustrated in FIG. 10B.

Also, in FIG. 10A, the gate insulating layer formed on the active fin has a uniform thickness on the side wall and the upper surface. In detail, it was confirmed that the thickness t1 of the gate insulating layer disposed on the upper surface of the active fin was 35.6 Å, which corresponds to about 102.59% of 34.7 Å, i.e., the thickness t2 of the region disposed on the side wall of the active fin. In contrast, in FIG. 10B, the thickness t1′ of the gate insulating layer in the region disposed on the upper surface of the active fin was 28.6 Å, which merely corresponds to 75.66% of 37.8 Å, i.e., the thickness t2′ of the region disposed on the side wall of the active fin, confirming that a uniform gate insulating was not secured.

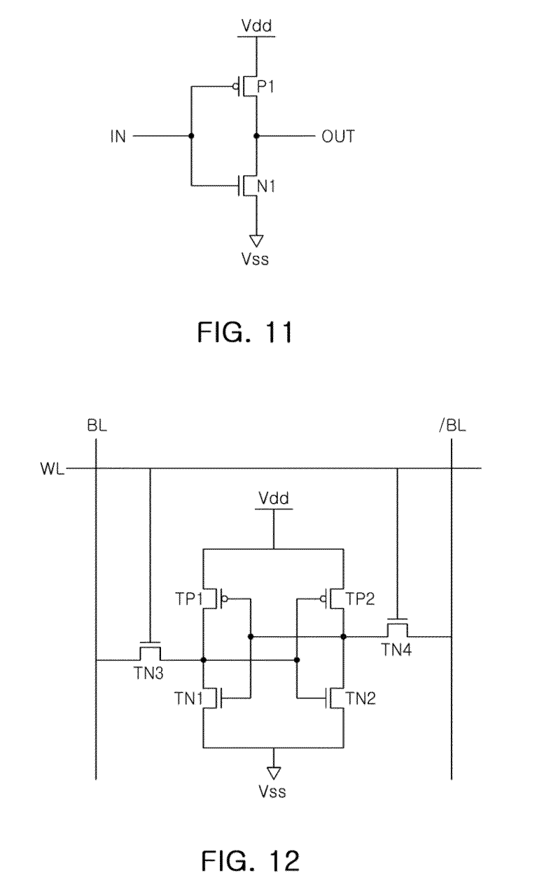

FIG. 11 is a circuit diagram of a complementary metal-oxide semiconductor (CMOS) inverter including a semiconductor device according to Example embodiments of inventive concepts.

Referring to FIG. 11, the CMOS inverter may include a PMOS transistor P1 and an NMOS transistor N1. The PMOS transistor P1 may be one of the semiconductor devices according to example embodiments described above. The PMOS and NMOS transistors may be connected in series between a power supply line Vdd and a ground line Vss, and input signals may be commonly input to gates of the PMOS and NMOS transistors. Output signals may be commonly output from drains of the PMOS and NMOS transistors. A driving voltage may be applied to a source of the PMOS transistor, and a ground voltage may be applied to a source of the NMOS transistor. The CMOS inverter may invert an input signal IN and output the inverted signal as an output signal OUT. In other words, when a logic level “1” is input as an input signal of the inverter, a logic level “0” may be output as an output signal, and when a logic level “0” is input as an input signal of the inverter, a logic level “1” may be output as an output signal.

FIG. 12 is a circuit diagram of a SRAM cell including a semiconductor device according to example embodiments of inventive concepts.

Referring to FIG. 12, in an SRAM device, one cell may include first and second driving transistors TN1 and TN2, first and second load transistors TP1 and TP2, and first and second access transistors TN3 and TN4. Here, sources of the first and second driving transistors TN1 and TN2 may be connected to a ground line Vss, and sources of the first and second load transistors TP1 and TP2 may be connected to a power supply line Vdd.

The first driving transistor TN1 configured as an NMOS transistor and the first load transistor TP1 configured as a PMOS transistor may form a first inverter, and the second driving transistor TN2 configured as an NMOS transistor and the second load transistor TP2 configured as a PMOS transistor may form a second inverter. The transistors forming the cells of the SRAM device may be one of the semiconductor devices according to example embodiments described above.

Output terminals of the first and second inverters may be connected to sources of the first access transistor TN3 and the second access transistor TN4, respectively. Also, in order to a single latch circuit, input terminals and output terminals of the first and second inverters may be connected in a crossing manner. Drains of the first and second access transistors TN3 and TN4 may be connected to first and second bit lines BL and /BL, respectively.

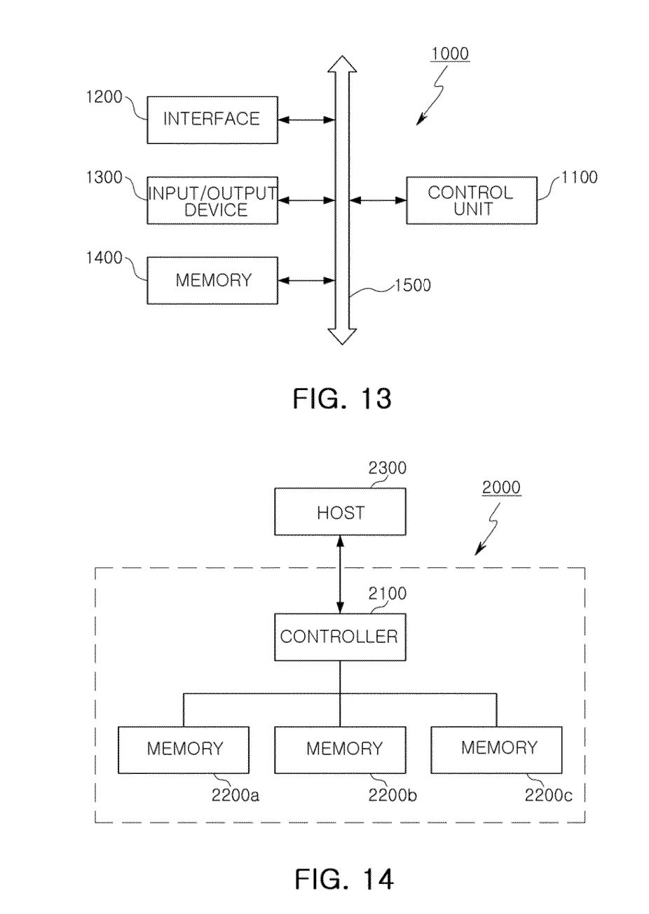

FIGS. 13 and 14 are block diagrams illustrating an electronic device and a storage device including a semiconductor device according to Example embodiments of inventive concepts, respectively.

Referring to FIG. 13, an electronic device 1000 including a semiconductor device according to example embodiments may include a control unit 1100, an interface 1200, an input/output device 1300, a memory 1400, and the like. The control unit 1100, the interface 1200, the input/output device 1300, the memory 1400, and the like, may be connected via a bus 1500 providing a passage through which data is delivered.

The control unit 1100 may include a device such as at least one among a microprocessor, a digital signal processor, and a microcontroller. The memory 1400 may include a device that may read and write data in various manners. The control unit 1100 and the memory 1400 may include at least one of the semiconductor devices according to example embodiments described above.

The input/output device 1300 may include a keypad, a keyboard, a touch screen device, a display device, an audio input/output module, and the like. The interface 1200 may be a module for transmitting and receiving data via a communication network, and may include an antenna, a wired/wireless transceiver, and the like. Besides the components illustrated in FIG. 13, the electronic device 1000 may further include an application chip set, an imaging device, and the like. The electronic device 1000 illustrated in FIG. 13 is not limited in terms of category, and may be various devices such as a personal digital assistant (PDA), a portable computer, a mobile phone, a wireless phone, a laptop computer, a memory card, a portable multimedia player, and a tablet PC.

Referring to FIG. 14, a storage device 2000 including a semiconductor device according to example embodiments may include a controller 2100 communicating with a host 2300 and memories 2200a, 2200b, and 2200c storing data. The controller 2100 and the memories 2200a, 2200b, and 2200c may include at least one of the semiconductor devices according to example embodiments described above.

The host 2300 communicating with the controller 2100 may be various electronic devices in which the storage device 200 is installed. For example, the host 2300 may be a smartphone, a digital camera, a desktop computer, a laptop computer, a portable media player, and the like. The controller 2100 may receive a data write or read request delivered from the host 2300 and store data in the memories 2200a, 2200b, and 2200c, or may generate a command CMD for retrieving data from the memories 2200a, 2200b, and 2200c.

As set forth above, according to example embodiments of inventive concepts, a semiconductor device including a fin-shaped field effect transistor (Fin-FET), allowing for high integration and securing a desired level of an upper width of an active fin to thus improve driving current characteristics, may be obtained.

According to example embodiments of inventive concepts, a method for effectively manufacturing the semiconductor device may be obtained.

It should be understood that example embodiments described herein should be considered in a descriptive sense only and not for purposes of limitation. Descriptions of features or aspects within each device or method according to example embodiments should typically be considered as available for other similar features or aspects in other devices or methods according to example embodiments. While some example embodiments have been particularly shown and described, it will be understood by one of ordinary skill in the art that variations in form and detail may be made therein without departing from the spirit and scope of the claims.

1. A semiconductor device comprising:
a substrate;
an isolation layer on the substrate, the isolation layer having a first surface opposite a second surface, the first surface being contiguous with the substrate; and
at least one active fin protruding from the substrate and including a first region having a side wall above the second surface of the isolation layer and a second region on the first region,
the second region having an upper surface,
the first region having a first width contiguous with the second surface of the isolation layer and a second width contiguous with the second region, and
the second width being in a range of 60% to 100% of the first width.

2. The semiconductor device of claim 1, wherein
the at least one active fin includes a corresponding active fin protruding above the isolation layer,
the first and second widths of the corresponding active are widths of the corresponding active fin at first and second heights with respect to the second surface of the isolation layer,
the first height is greater than 0% and less than or equal to 6% of a height of the corresponding active fin protruding above the isolation layer, and
the second height is greater than or equal to 85% of the height of the corresponding active fin protruding above the isolation layer and less than the height of the corresponding active fin protruding above the isolation layer.

3. The semiconductor device of claim 1, wherein
the at least one active fin includes a corresponding active fin protruding above the isolation layer,
the first width of the corresponding active fin is a width at a level 2 nm higher than the second surface of the isolation layer, and
the second width is a width of the corresponding active fin at a level 5 nm lower than a height of the corresponding active fin protruding above the isolation layer.

4. The semiconductor device of claim 1, wherein
the second width has a size ranging from 60% to 75% of the first width.

5. The semiconductor device of claim 1, wherein the upper surface is a curved surface, and a radius of curvature of the upper surface ranges from 3.5 nm to 5 nm.

6. The semiconductor device of claim 1, wherein
the at least one active fin includes a corresponding active fin,
a side wall of the corresponding active fin has an angle ranging from 85° to 90° with respect to the second surface of the isolation layer.

7. The semiconductor device of claim 1, wherein a side wall of the at least one active fin has a crystal structure in which a crystal plane is a (110) plane.

8. The semiconductor device of claim 1, further comprising:
a gate insulating layer including a first insulating layer and a second insulating layer on the first insulating layer, wherein
the at least one active fin includes a corresponding active fin,
the gate insulating layer is on the corresponding active fin, wherein
the gate insulating layer covers a side wall and the upper surface of the corresponding active fin.

9. The semiconductor device of claim 8, wherein a thickness of the second insulating layer is greater than a thickness of the first insulating layer.

10. The semiconductor device of claim 9, wherein
the thickness of the first insulating layer ranges from 20 Å to 35 Å, and
the thickness of the second insulating layer ranges from 35 Å to 45 Å.

11. The semiconductor device of claim 8, wherein
the first and second insulating layer are formed of a same material.

12. The semiconductor device of claim 8, wherein
a thickness of a region of the gate insulating layer on the upper surface of the corresponding active fin is 96% to 106% of a thickness of a region of the gate insulating layer on the side wall of the corresponding active fin.

13. The semiconductor device of claim 8, further comprising:
a gate electrode on the gate insulating layer.

14. A semiconductor device comprising:
a substrate;
an isolation layer on the substrate, the isolation layer having a first surface opposite a second surface, the first surface being contiguous with the substrate; and
at least one active fin on the substrate,
the at least one active fin including a corresponding active fin,
the corresponding active fin having a side wall protruding from the second surface of the isolation layer,
the corresponding active fin having an upper surface,
the corresponding active fin including a region in which a width thereof increases in a direction toward the substrate from the upper surface, and
a height at which a width of the corresponding active fin is 4 nm is a height equal to 97% or greater of the height of the corresponding active fin and less than the height of the corresponding active fin.

15. The semiconductor device of claim 14, wherein the height at which the width of the corresponding active fin is 4 nm is at a level 0.3 nm to 0.9 nm lower than the height of the corresponding active fin.

16. A semiconductor device comprising:
a substrate including a trench that defines an active fin,
the protruding region and the buried region each respectively including a central axis that extends in a height direction thereof,
a difference in angle between the central axis of the buried region and the central axis of the protruding region ranging from 0° to 3°,
the protruding region including a first region and a second region that is above the first region,
the second region including a curved upper surface; and
an isolation layer in the trench, the isolation layer surrounding the buried region of the active fin such that the protruding region of the active fin protrudes above the isolation layer.

17. The semiconductor device of claim 16, further comprising:
a gate insulating layer covering the protruding region; and
a gate electrode on the gate insulating layer, wherein
the gate insulating layer covers the curved upper surface of the second region of the protruding region,
the gate insulating extends from the curved upper surface to cover a sidewall of the protruding region along the first and second region, and
a thickness of the gate insulating layer on the curved upper surface of the second region is 96% to 106% of a thickness of the gate insulating layer along the sidewall of the protruding region at the first region of the protruding region.

18. The semiconductor device of claim 17, wherein
the gate insulating layer includes a first insulating layer and a second insulating layer, and
the thickness of the first insulating layer ranges from 20 Å to 35 Å, and the thickness of the second insulating layer ranges from 35 Å to 45 Å.

19. The semiconductor device of claim 16, wherein the curved upper surface of the second region has a radius of curvature that ranges from 3.5 nm to 5 nm.

20. The semiconductor device of claim 16, wherein
the protruding region has a first width at a first height and a second width at a second height,
the first height is greater than 0% of a height of the protruding region and less than or equal to 6% of the height of the protruding region,
the second height is less than the height of the protruding region and greater than 85% of the height of the protruding region, and
the second width has a size ranging from 60% to 75% of the first width.

21.-40. (canceled)
